(19) United States
(12) Patent Application Publication
(10) Pub. No.: US 2015/0270234 A1
(43) Pub. Date: Sep. 24, 2015

(54) PAD STRUCTURE FOR SEMICONDUCTOR DEVICE CONNECTION

(71) Applicant: Semiconductor Manufacturing International (Shanghai) Corporation, Shanghai (CN)

(72) Inventors: Hongwei LI, Shanghai (CN); Jing LIU, Shanghai (CN); Huijuan CHENG, Shanghai (CN); Jie CHEN, Shanghai (CN)

(21) Appl. No.: 14/657,926

(22) Filed: Mar. 13, 2015

(30) Foreign Application Priority Data
Mar. 24, 2014 (CN) 201410114829.4

(51) Int. Cl. H01L 23/00

(52) U.S. Cl. CPC H01L 24/05; H01L 2224/05008

(57) ABSTRACT

A pad structure may include a conductive pad that includes an exposed portion. The pad structure may further include a first conductive set that includes a first conductive part and a second conductive part. The first conductive part may overlap the exposed portion in a direction perpendicular to the conductive pad. The first conductive part may be spaced from the second conductive part in a direction parallel to the conductive pad and may overlap the second conductive part in the direction parallel to the conductive pad. The pad structure may further include a conductive layer that contacts the conductive pad and is positioned between the conductive pad and the first conductive set in the direction perpendicular to the conductive pad. The pad structure may further include a first via member, which may electrically connect the first conductive part to the conductive layer.

### CROSS-REFERENCE TO RELATED APPLICATION

This application claims priority to and benefit of Chinese Patent Application No. 201410114829.4, filed on 25 Mar. 2014, the Chinese Patent Application being incorporated herein by reference in its entirety.

### BACKGROUND OF THE INVENTION

The present invention is related to a pad structure that may be used for electrically connecting a semiconductor device and/or a semiconductor die to other devices.

In general, a semiconductor device package may include pad structures for electrically connecting a semiconductor die, which may have one or more electric circuits, to other devices through conductive leads (or pins). A pad structure may include one or more metal layers overlapping one or more dielectric layers. A plurality of metal layers may complicate underlying circuit wiring and may significantly add to the cost of the associated semiconductor die.

### SUMMARY

An embodiment of the present invention may be related to a pad structure. The pad structure may include a conductive pad that includes an exposed portion. The pad structure may further include a first conductive set, which may include a first conductive part and a second conductive part. The first conductive part may overlap the exposed portion in a direction perpendicular to (e.g., an exposed surface of) the conductive pad. The first conductive part may be spaced from the second conductive part in a direction parallel to the conductive pad and may overlap the second conductive part in the direction parallel to the conductive pad. The pad structure may further include a conductive layer that contacts the conductive pad and is positioned between the conductive pad and the first conductive set in the direction perpendicular to the conductive pad. The pad structure may further include a first via member, which may electrically connect the first conductive part to the conductive layer in the direction perpendicular to the conductive pad.

The pad structure may include a second via member, which electrically connects the second conductive part to the conductive layer in the direction perpendicular to the conductive pad.

The second conductive part may overlap the exposed portion in the direction perpendicular to the conductive pad.

The first conductive set may include a third conductive part positioned between the first conductive part and the second conductive part and is spaced from each of the first conductive part and the second conductive part, and no via member may electrically connect the third conductive part to the conductive layer.

The conductive pad may further include a covered portion that is connected to the exposed portion, the second conductive part may overlap the covered portion in the direction perpendicular to the conductive pad, the first conductive set may include a third conductive part positioned between the first conductive part and the second conductive part and is spaced from each of the first conductive part and the second conductive part, and no via member may electrically connect the third conductive part to the conductive layer.

The pad structure may include a third via member, which may electrically connect the first conductive part to the conductive layer in the direction perpendicular to the conductive pad. The pad structure may include a fourth via member, which may electrically connect the second conductive part to the conductive layer in the direction perpendicular to the conductive pad. A distance between the first via member and the third via member may be different from, e.g., greater than, a distance between the second via member and the fourth via member.

The pad structure may include a second conductive set, which may include a third conductive part and a fourth conductive part, wherein the first conductive set may be positioned between the conductive layer and the second conductive set, wherein the third conductive part overlaps the exposed portion in the direction perpendicular to the conductive pad, and wherein the third conductive part may be spaced from the fourth conductive part in the direction parallel to the conductive pad and overlaps the fourth conductive part in the direction parallel to the conductive pad. The pad structure may include a second via member, which electrically connects a conductive part of the first conductive set and a conductive part of the second conductive set in the direction perpendicular to the conductive pad.

The number of conductive parts of the second conductive set may be unequal to the number of conductive parts of the first conductive set.

The third conductive part may be larger than the first conductive part.

The second via member may electrically connect the first conductive part to the third conductive part.

The second conductive part may overlap the exposed portion in the direction perpendicular to the conductive pad, and no via member may electrically connect the second conductive part to either of the conductive layer and the second conductive set.

The pad structure may include a third via member. The second conductive part may overlap the exposed portion in the direction perpendicular to the conductive pad, the third via member may electrically connect the second conductive part to the second conductive set in the direction perpendicular to the conductive pad, and no via member may electrically connect the second conductive part to the conductive layer in the direction perpendicular to the conductive pad.

The third via member may electrically connect the second conductive part to the fourth conductive part in the direction perpendicular to the conductive pad.

No via member may electrically connect the first conductive part to the second conductive set.

The second via member may electrically connect the second conductive part to the third conductive part, and the second conductive part may overlap the exposed portion. No via member may electrically connect the second conductive part to the conductive layer.

The pad structure may include a first passivation layer, which may overlap a covered portion of the conductive pad and may have an opening that exposes the exposed portion of the conductive pad. The pad structure may include a second passivation layer, which may overlap the first passivation layer, wherein the covered portion of the conductive pad may be positioned between the first passivation layer and the second passivation layer.

The second passivation layer may be thicker than the first passivation layer.

The exposed portion of the conductive pad may be thicker than the second passivation layer and/or may be thicker than the covered portion of the conductive pad. A thickness of the exposed portion of the conductive pad may be equal to a sum of a thickness of the second passivation layer and a thickness of the covered portion of the conductive pad.

The conductive pad may be formed of aluminum. The conductive layer may be formed of copper.

According to embodiments of the invention, the discrete structures of the conductive sets and the associated via member connection structure may effectively facilitate structural support and stress release (e.g., during a bonding process) in the pad structure and may function as part of the electric circuits underlying the conductive pad. Therefore, embodiments of the invention may provide advantages related to one or more of reliability, quality, cost, size, etc. for pad structures.

The above summary is related to one or more of many embodiments of the invention disclosed herein and is not intended to limit the scope of the invention.

### BRIEF DESCRIPTION OF THE DRAWINGS

FIG. 1A shows a schematic cross-sectional view that illustrates elements of a pad structure in accordance with an embodiment of the present invention.

FIG. 1B shows a schematic cross-sectional view that illustrates elements of a pad structure in accordance with an embodiment of the present invention.

FIG. 2A shows a schematic cross-sectional view that illustrates elements of a pad structure in accordance with an embodiment of the present invention.

FIG. 2B shows a schematic cross-sectional view that illustrates elements of a pad structure in accordance with an embodiment of the present invention.

FIG. 2C shows a schematic cross-sectional view that illustrates elements of a pad structure in accordance with an embodiment of the present invention.

FIG. 2D shows a schematic cross-sectional view that illustrates elements of a pad structure in accordance with an embodiment of the present invention.

### DETAILED DESCRIPTION

Example embodiments of the present invention are described with reference to the accompanying drawings. As those skilled in the art would realize, the described embodiments may be modified in various different ways, all without departing from the spirit or scope of the present invention. Embodiments of the present invention may be practiced without some or all of these specific details. Well known process steps and/or structures may not have been described in detail in order to not unnecessarily obscure the present invention.

The drawings and description are illustrative and not restrictive. Like reference numerals may designate like (e.g., analogous or identical) elements in the specification. Repetition of description may be avoided.

The relative sizes and thicknesses of elements shown in the drawings are for facilitate description and understanding, without limiting the present invention. In the drawings, the thicknesses of some layers, films, panels, regions, etc., may be exaggerated for clarity.

Illustrations of example embodiments in the figures may represent idealized illustrations. Variations from the shapes illustrated in the illustrations, as a result of, for example, manufacturing techniques and/or tolerances, may be possible. Thus, the example embodiments should not be construed as limited to the shapes or regions illustrated herein but are to include deviations in the shapes. For example, an etched region illustrated as a rectangle may have rounded or curved features. The shapes and regions illustrated in the figures are illustrative and should not limit the scope of the example embodiments.

Although the terms “first”, “second”, etc. may be used herein to describe various elements, these elements, should not be limited by these terms. These terms may be used to distinguish one element from another element. Thus, a first element discussed below may be termed a second element without departing from the teachings of the present invention. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

If a first element (such as a layer, film, region, or substrate) is referred to as being “on”, “neighboring”, “connected to”, or “coupled with” a second element, then the first element can be directly on, directly neighboring, directly connected to, or directly coupled with the second element, or an intervening element may also be present between the first element and the second element. If a first element is referred to as being “directly on”, “directly neighboring”, “directly connected to”, or “directed coupled with” a second element, then no intended intervening element (except environmental elements such as air) may also be present between the first element and the second element.

Spatially relative terms, such as “beneath”, “below”, “lower”, “above”, “upper”, and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein should be interpreted accordingly.

The terminology used herein is for the purpose of describing particular embodiments and is not intended to limit the invention. As used herein, the singular forms, “a”, “an”, and “the” may indicate plural forms as well, unless the context clearly indicates otherwise. The terms “includes” and/or “including”, when used in this specification, may specify the presence of stated features, integers, steps, operations, elements, and/or components, but may not preclude the presence or addition of one or more other features, integers, steps, operations, elements, components, and/or groups.

Unless otherwise defined, terms (including technical and scientific terms) used herein have the same meanings as commonly understood by one of ordinary skill in the art related to this invention. Terms, such as those defined in commonly used dictionaries, should be interpreted as having meanings that are consistent with their meanings in the context of the relevant art and should not be interpreted in an idealized or overly formal sense unless expressly so defined herein.

The term “connect” may mean “electrically connect”. The term “insulate” may mean “electrically insulate”. The term “conductive” may mean “electrically conductive”.

Unless explicitly described to the contrary, the word “comprise” and variations such as “comprises”, “comprising”, “include”, or “including” may imply the inclusion of stated elements but not the exclusion of other elements.

Various embodiments, including methods and techniques, are described in this disclosure. Embodiments of the invention may also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out operations pertaining to embodiments of the invention. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments of the invention.

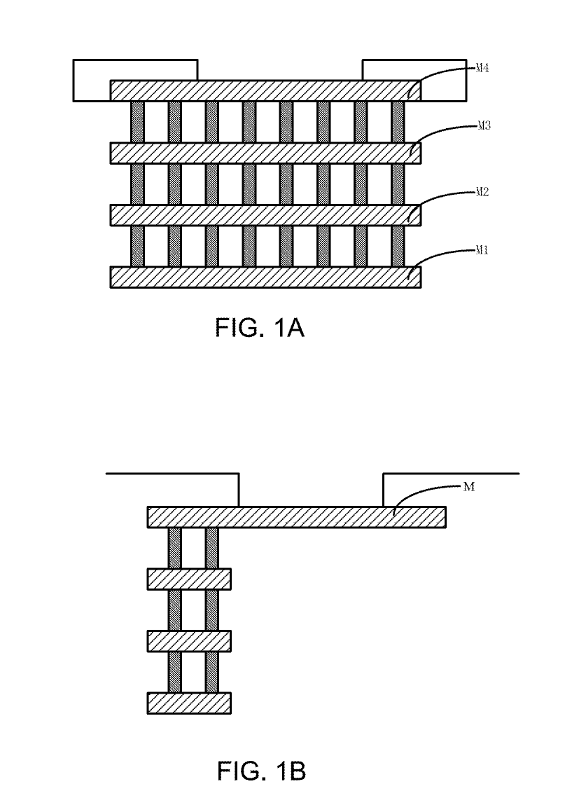

FIG. 1A shows a schematic cross-sectional view that illustrates elements of a pad structure in accordance with an embodiment of the present invention. The pad structure may include an exposed metal layer M4 that is exposed through an opening. The pad structure may further include a plurality of other metal layers, such as metal layers M1, M2, and M3, overlapping the exposed metal layer M4 and overlapping the position of the opening in a direction perpendicular to the exposed metal layer M4. The pad structure may be able to withstand substantial pressure.

FIG. 1B shows a schematic cross-sectional view that illustrates elements of a pad structure in accordance with an embodiment of the present invention. The pad structure may include an exposed metal layer M that is exposed through an opening and may not include other metal layers that overlap the position of the opening in a direction perpendicular to the exposed metal layer M.

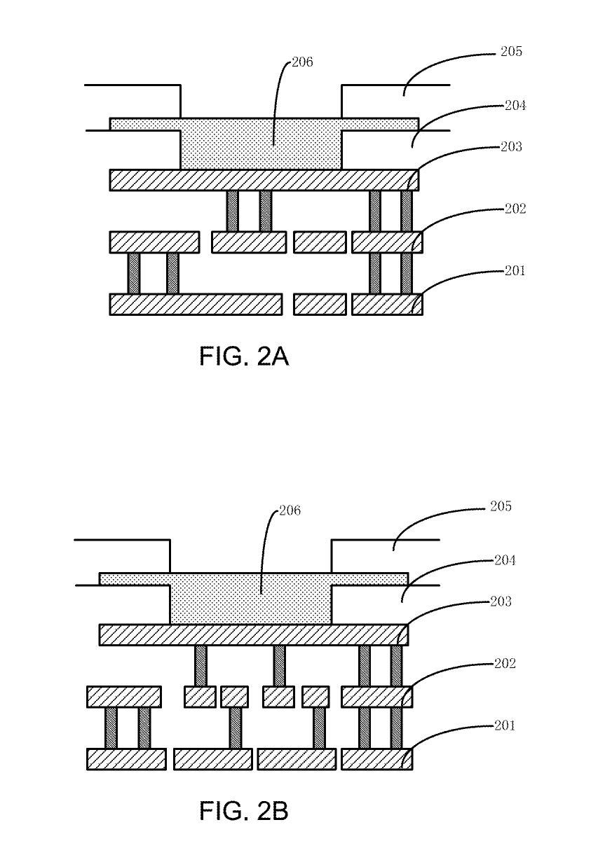

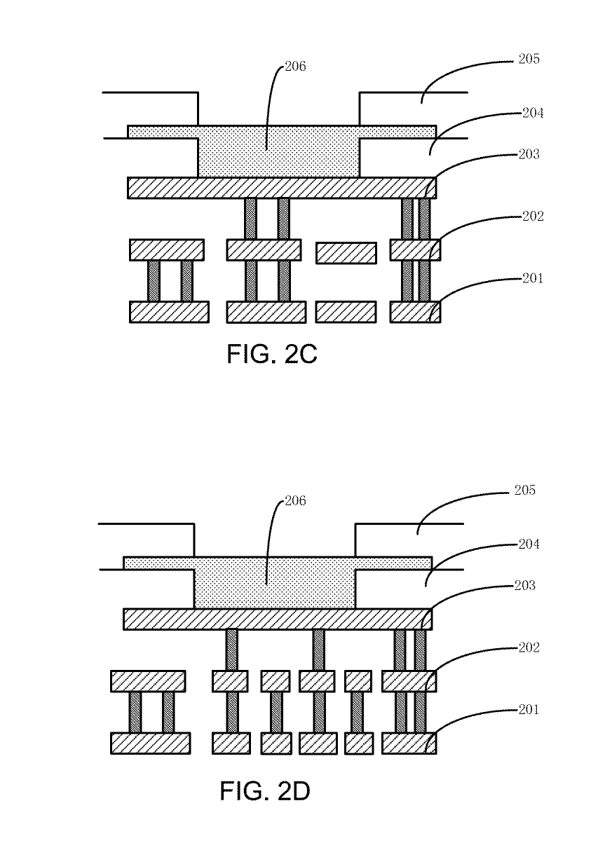

FIG. 2A shows a schematic cross-sectional view that illustrates elements of a pad structure in accordance with an embodiment of the present invention. FIG. 2B shows a schematic cross-sectional view that illustrates elements of a pad structure in accordance with an embodiment of the present invention. FIG. 2C shows a schematic cross-sectional view that illustrates elements of a pad structure in accordance with an embodiment of the present invention. FIG. 2D shows a schematic cross-sectional view that illustrates elements of a pad structure in accordance with an embodiment of the present invention.

A pad structure according to an embodiment of the present invention may include a conductive pad 206 that includes an exposed portion having an exposed surface for contacting a lead (or pin) of a semiconductor package. The conductive pad 206 may be formed of a metal material, such as aluminum. A surface of the conductive pad 206 that includes the exposed surface may be larger than a surface of the conductive pad 206 that is opposite the exposed surface, for optimum structural robustness and/or electrical contact of the pad structure. In an embodiment, the conductive pad 206 may have a T-shaped cross-section.

The pad structure may further include a first passivation layer 205, which may overlap a covered portion of the conductive pad 206 and may have an opening that exposes the exposed portion of the conductive pad 206. The first passivation layer 205 may be formed of an insulating material, such as an oxide.

The pad structure may further include a second passivation layer 204, which may overlap the first passivation layer 205. The covered portion of the conductive pad 206 may be positioned between the first passivation layer 205 and the second passivation layer 204. The second passivation layer 205 may be formed of an insulating material, such as an oxide. The second passivation layer 204 may be thicker than the first passivation layer 205.

The exposed portion of the conductive pad 206 may be thicker than the second passivation layer 204 and/or may be thicker than the covered portion of the conductive pad 206. A thickness of the exposed portion of the conductive pad 206 may be equal to a sum of a thickness of the second passivation layer 204 and a thickness of the covered portion of the conductive pad 206 in a direction perpendicular to (e.g., the exposed surface of) the conductive pad 206.

The pad structure may further include a first conductive set 202, which may include a plurality of conductive parts, such as a first conductive part and a second conductive part. The first conductive part, e.g., the center-left conductive part of the first conductive set 202 illustrated in FIG. 2A or 2C, or the left mid-sized conductive part of the first conductive set 202 illustrated in FIG. 2B or 2D, may overlap the exposed portion in the direction perpendicular to the conductive pad 206. The first conductive part may be spaced from the second conductive part in a direction parallel to the conductive pad 206 and may overlap the second conductive part in the direction parallel to (e.g., the exposed surface of) the conductive pad 206.

The conductive parts may be formed of a metal material. The conductive parts may have equal or different sizes. The conductive parts may have identical, similar, or different shapes. The conductive parts may have one or more shapes, such as one or more of rectangle shapes, square shapes, rhombus shapes, polygon shapes, etc. The number of the conductive parts and/or distances between the conductive parts may be configured according to particular embodiments.

The pad structure may further include a conductive layer 203 that may directly and/or electrically contact the conductive pad 206 and may be positioned between the conductive pad 206 and the first conductive set 202 in the direction perpendicular to the conductive pad 206. The interface between the conductive layer 203 and the conductive pad 206 may be sufficiently large, for ensuring sufficient bonding and/or sufficient electrical connectivity. The conductive layer 203 may be electrically connected to some (e.g., half or 50%) of the conductive parts of the first conductive set 202 and may be electrically insulated from others of the conductive parts of the first conductive set 202. The conductive layer 203 may be formed of a metal material, such as copper. The pad structure may include a passivation material layer and/or an insulation material layer that may isolate the conductive layer 203 from various active components.

The pad structure may further include a second conductive set 201, which may include a plurality of conductive parts, such as a third conductive part and a fourth conductive part. The first conductive set 202 may be positioned between the conductive layer 203 and the second conductive set 201. The third conductive part, e.g., the leftmost conductive part of the second conductive set 201 illustrated in FIG. 2A, the center-left conductive part of the second conductive set 201 illustrated in FIG. 2B or 2C, or the left mid-sized conductive part of the second conductive set 201 illustrated in FIG. 2D, may overlap the exposed portion of the conductive pad 206 in the direction perpendicular to the conductive pad 206. The third conductive part may be spaced from the fourth conductive part in the direction parallel to the conductive pad 206 and may overlap the fourth conductive part in the direction parallel to the conductive pad 206.

Analogous to the conductive parts of the first conductive set 202, the number, material, sizes, shapes, distances, etc., of the conductive parts of the second conductive set 201 may be configured according to particular embodiments.

In an embodiment, as illustrated in FIG. 2A, the third conductive part may be larger than the first conductive part.

In an embodiment, as illustrated in FIG. 2B, the number of conductive parts in the first conductive set 202 may be different from, e.g., greater than, the number of conductive parts in the second conductive set 201.

The pad structure may further include a plurality of via members. Each via member of the via members may be a conductive member that extends through a via structure positioned in a dielectric layer of the pad structure and may electrically connect different conductive elements in the pad structure.

As illustrated in FIGS. 2A to 2D, some of the via members may provide electrical connection and structural support between the first conductive set 202 and the conductive layer 203, and some of the via members may provide electrical connection and structural support between the first conductive set 202 and the second conductive set 201.

In an embodiment, as illustrated in FIG. 2A, at least a first via member may electrically connect the first conductive part (e.g., center-left conductive part of the first conductive set 202) and the conductive layer 203 in the direction perpendicular to the conductive pad 206.

The first via member may overlap the exposed portion of the conductive pad 206 and may facilitate stress release and structural support for the pad structure, e.g., in a bonding process. Advantageously, damage to the pad structure and the associated semiconductor die may be prevented or minimized, and the quality of the associated semiconductor device package may be ensured.

In an embodiment, a second via member may electrically connect a conductive part of the first conductive set 202 and a conductive part of the second conductive set 201 in the direction perpendicular to the conductive pad 206.

In an embodiment, a second via member may electrically connect the second conductive part (e.g., the rightmost conductive part of the first conductive set 202 illustrated in FIG. 2A) and the conductive layer 203 in the direction perpendicular to the conductive pad 206.

In an embodiment, as illustrated in FIG. 2A, the first conductive set 202 may include a third conductive part (e.g., the center-right conductive part of the first conductive set 202) positioned between the first conductive part (e.g., the center-left conductive part of the first conductive set 202) and the second conductive part (e.g., the rightmost conductive part of the first conductive set 202) and is spaced from each of the first conductive part and the second conductive part, and no via member may electrically connect the third conductive part to the conductive layer 203.

In an embodiment, as illustrated in FIG. 2C, the second conductive part (e.g., the rightmost conductive part of the first conductive set 202) may overlap the covered portion in the direction perpendicular to the conductive pad 206, the first conductive set 202 may include a fifth conductive part (e.g., the center-right conductive part of the first conductive set 202) positioned between the first conductive part (e.g., the center-left conductive part of the first conductive set 202) and the second conductive part and is spaced from each of the first conductive part and the second conductive part, and no via member may electrically connect the fifth conductive part to the conductive layer 203. A first via and a third via member may electrically connect the first conductive part to the conductive layer 203 in the direction perpendicular to the conductive pad 206. A second via and a fourth via member may electrically connect the second conductive part to the conductive layer 203 in the direction perpendicular to the conductive pad 206. A distance between the first via member and the third via member may be different from, e.g., greater than, a distance between the second via member and the fourth via member.

In an embodiment, as illustrated in FIG. 2C, a second via member may electrically connect the first conductive part (e.g., the center-left conductive part of the first conductive set 202) and the third conductive part (e.g., the center-left conductive part of the second conductive set 201).

In an embodiment, as illustrated in FIG. 2A, the second conductive part (the center-right conductive part of the first conductive set 202) may overlap the exposed portion in the direction perpendicular to the conductive pad 206, and no via member may electrically connect the second conductive part to either of the conductive layer 203 and the second conductive set 201.

In an embodiment, as illustrated in FIG. 2B, the second conductive part (e.g., one of the two smallest conductive parts of the first conductive set 202) may overlap the exposed portion in the direction perpendicular to the conductive pad 206, a third via member may electrically connect the second conductive part to the second conductive set 201 in the direction perpendicular to the conductive pad 206, and no via member may electrically connect the second conductive part to the conductive layer 203 in the direction perpendicular to the conductive pad 206. The third via member may electrically connect the second conductive part to the fourth conductive part (e.g., one of the two center conductive parts of the second conductive set 201) in the direction perpendicular to the conductive pad 206. The size of the second conductive part may be different from, e.g., smaller than, the fourth conductive part. No via member may electrically connect the first conductive part (e.g., one of the two medium-sized conductive parts of the first conductive set 202) and the second conductive set 201.

Conductive parts of the first conductive set 202 and/or the second conductive set 201 that are not electrically connected to the conductive layer 203 may function as part of the electric circuits underlying the conductive pad 206.

The pad structure may include one or more additional conductive sets analogous to and overlapping the first conductive set 202 and/or the second conductive set 201 and may include associated via members.

An embodiment of the invention may be related to a method for manufacturing a pad structure, such as a pad structure discussed with reference to one or more of FIGS. 2A to 2D.

The method may include the following steps: preparing a first dielectric layer; patterning the dielectric layer to form trenches in the dielectric layer; filling the trenches with a metal material to form the second conductive set 201; performing planarization on the combination of the patterned first dielectric layer and the second conductive set 201 using a second dielectric layer; forming a first via member set (which is connected to the second conductive set 201 and extends through the second dielectric layer), wherein the first set of via members may be formed of a conductive material, such as copper or aluminum; performing analogous steps to form the first conductive set 202 (which is connected to the first via member set) in a third dielectric layer and to form a second via member set (which is connected to the first conductive set 202 and extends through a fourth dielectric layer); preparing a fifth dielectric layer; forming a single opening in the fifth dielectric layer; depositing metal in the opening to form the conductive layer 203 (which is connected to the second via member set); depositing first passivation material layer on the conductive layer 203; etching the first passivation material layer to form the second passivation layer 204, which has an hole that exposes the conductive layer 203, wherein the position of the hole overlaps one more or more positions of one or more via members of the aforementioned via member sets; depositing a metal material set in the hole to form the conductive pad 206; depositing a second passivation material layer on the conductive pad; and patterning the second passivation material layer to form the first passivation layer 205, which has an opening that exposes the exposed portion of the conductive pad 206.

Alternative or additional steps may be performed for forming the pad structure. For example, additional discrete conductive sets and related via members may be formed prior to the formation of the second conductive set 201 using process steps analogous to those used for forming the second conductive set 201 and associated via members.

According to embodiments of the invention, the discrete (or spaced) structures of the first conductive set 202 and/or the second conductive set 201 and the associated via member connection structure may effectively facilitate structural support and stress release, e.g., during a bonding process, and may function as part of the electric circuits underlying the conductive pad 206. Therefore, embodiments of the invention may provide advantages related to one or more of reliability, quality, cost, size, etc. for pad structures.

While this invention has been described in terms of several embodiments, there are alterations, permutations, and equivalents, which fall within the scope of this invention. It should also be noted that there are many alternative ways of implementing the methods and apparatuses of the present invention. Furthermore, embodiments of the present invention may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

What is claimed is:

1. A pad structure comprising:
a conductive pad that includes an exposed portion;
a first conductive set, which includes a first conductive part and a second conductive part, wherein the first conductive part overlaps the exposed portion in a direction perpendicular to the conductive pad, and wherein the first conductive part is spaced from the second conductive part in a direction parallel to the conductive pad and overlaps the second conductive part in the direction parallel to the conductive pad;
a conductive layer that contacts the conductive pad and is positioned between the conductive pad and the first conductive set in the direction perpendicular to the conductive pad; and
a first via member, which electrically connects the first conductive part to the conductive layer.

2. The pad structure of claim 1, further comprising: a second via member, which electrically connects the second conductive part to the conductive layer.

3. The pad structure of claim 2, wherein the second conductive part overlaps the exposed portion in the direction perpendicular to the conductive pad.

4. The pad structure of claim 3, wherein the first conductive set further includes a third conductive part positioned between the first conductive part and the second conductive part and is spaced from each of the first conductive part and the second conductive part, and wherein no via member electrically connects the third conductive part to the conductive layer.

5. The pad structure of claim 2, wherein the conductive pad further includes a covered portion that is connected to the exposed portion, and wherein the second conductive part overlaps the covered portion in the direction perpendicular to the conductive pad.

6. The pad structure of claim 5, wherein the first conductive set further includes a third conductive part positioned between the first conductive part and the second conductive part and is spaced from each of the first conductive part and the second conductive part, and wherein no via member electrically connects the third conductive part to the conductive layer.

7. The pad structure of claim 2, further comprising:
a third via member, which electrically connects the first conductive part to the conductive layer; and
a fourth via member, which electrically connects the second conductive part to the conductive layer,
wherein a distance between the first via member and the third via member is different from a distance between the second via member and the fourth via member.

8. The pad structure of claim 1, further comprising:
a second conductive set, which includes a third conductive part and a fourth conductive part, wherein the first conductive set is positioned between the conductive layer and the second conductive set, wherein the third conductive part overlaps the exposed portion in the direction perpendicular to the conductive pad, and wherein the third conductive part is spaced from the fourth conductive part in the direction parallel to the conductive pad and overlaps the fourth conductive part in the direction parallel to the conductive pad; and
a second via member, which electrically connects a conductive part of the first conductive set and a conductive part of the second conductive set.

9. The pad structure of claim 8, wherein the third conductive part is larger than the first conductive part.

10. The pad structure of claim 8, wherein the second via member electrically connects the first conductive part to the third conductive part.

11. The pad structure of claim 10, wherein the second conductive part overlaps the exposed portion in the direction perpendicular to the conductive pad, and wherein no via member electrically connects the second conductive part to either of the conductive layer and the second conductive set.

12. The pad structure of claim 10, further comprising: a third via member, wherein the second conductive part overlaps the exposed portion in the direction perpendicular to the conductive pad, wherein the third via member electrically connects the second conductive part to the second conductive set, and wherein no via member electrically connects the second conductive part to the conductive layer.

13. The pad structure of claim 12, wherein the third via member electrically connects the second conductive part to the fourth conductive part.

14. The pad structure of claim 8, wherein no via member electrically connects the first conductive part to the second conductive set.

15. The pad structure of claim 14, wherein the second via member electrically connects the second conductive part to the third conductive part, and wherein the second conductive part overlaps the exposed portion.

16. The pad structure of claim 15, wherein no via member electrically connects the second conductive part to the conductive layer.

17. The pad structure of claim 1, further comprising:
a first passivation layer, which overlaps a covered portion of the conductive pad and has an opening that exposes the exposed portion of the conductive pad; and
a second passivation layer, which overlaps the first passivation layer, wherein the covered portion of the conductive pad is positioned between the first passivation layer and the second passivation layer.

18. The pad structure of claim 17, wherein the second passivation layer is thicker than the first passivation layer.

19. The pad structure of claim 17, wherein the exposed portion of the conductive pad is thicker than at least one of the second passivation layer and the covered portion of the conductive pad.

20. The pad structure of claim 1, wherein the conductive pad is formed of aluminum, and wherein the conductive layer is formed of copper.
